(19) United States
(12) Patent Application Publication
(10) Pub. No.: US 2015/0069575 A1
(43) Pub. Date: Mar. 12, 2015

(54) NITRIDE SEMICONDUCTOR GROWTH APPARATUS, AND EPITAXIAL WAFER FOR NITRIDE SEMICONDUCTOR POWER DEVICE

(71) Applicant: SHARP KABUSHIKI KAISHA, Osaka-shi, Osaka (JP)

(72) Inventor: Nobuaki Teraguchi, Osaka-shi (JP)

(73) Assignee: SHARP KABUSHIKI KAISHA, Osaka-shi, Osaka (JP)

(21) Appl. No.: 14/394,584

(22) PCT Filed: Feb. 28, 2013
(86) PCT No.: PCT/JP2013/055366

§ 371 Date: Oct. 15, 2014

(30) Foreign Application Priority Data
Apr. 26, 2012 (JP) 2012-101383

(51) Int. Cl. C30B 25/08; C30B 29/40; H01L 29/20

(52) U.S. Cl. CPC C30B 25/08; H01L 29/2003; C30B 29/406
USPC 257/615; 118/715; 118/733

(57) ABSTRACT

A nitride semiconductor growth apparatus of the present invention comprises a chamber into which a reactive gas containing nitrogen is to be introduced as a material gas and a reaction part which is placed in the chamber and in which the material gas is brought into reaction to grow a nitride semiconductor. In the nitride semiconductor growth apparatus, in a region which includes a reaction part and part of an upstream side from a reaction part with respect to a flow of a material gas, portions to be in contact with the material gas (a gas introducing part, a current introducing part and a view port part and the like) are made from non-copper material (i.e., material containing no copper).

### TECHNICAL FIELD

The present invention relates to a nitride semiconductor growth apparatus for growing a nitride semiconductor, and to an epitaxial wafer for nitride semiconductor power devices. For example, the invention relates to a nitride semiconductor growth apparatus suitable for growth of a nitride semiconductor epitaxial wafer having a superior current collapse characteristic.

### BACKGROUND ART

PTL1 (JP 2007-184379 A) describes a conventional semiconductor growth apparatus in which Cu is added as transition metal atoms to group III nitride semiconductor crystals so that group III atomic vacancies are filled with Cu atoms, with the group III atomic vacancy density lowered and the resistance value of the group III nitride semiconductor crystals increased.

This PTL1 also describes that with use of a substrate formed of group III nitride semiconductor crystals with their resistance value increased, a GaN channel layer and an AlGaN electron supply layer are formed on the substrate to make up a transistor, so that large amounts of holes are blocked from moving to the GaN channel layer, preventing the function of the GaN channel layer from being impaired by such move of the holes.

### CITATION LIST

### Patent Literatures

PTL1: JP 2007-184379 A

### SUMMARY OF INVENTION

### Technical Problem

However, the present inventors found out for the first time that contrary to the description of PTL1, contamination of a nitride semiconductor by copper (Cu), if involved during growth process of the nitride semiconductor, triggers the current collapse.

For electron devices using a nitride semiconductor, such current collapse has been an important issue that the on-resistance in high-voltage operation is increased as compared with the on-resistance in low-voltage operation.

Accordingly, an object of the present invention is to provide a nitride semiconductor growth apparatus, as well as an epitaxial wafer for nitride semiconductor power devices, capable of fabricating a nitride semiconductor enabled to suppress the current collapse.

### Solution to Problem

The present inventors found out that through analyses of various wafer contaminations, contamination of Cu is detected in every case without exception.

Then, the present inventors found out for the first time that contamination of the nitride semiconductor by copper (Cu), if involved in growth process of the nitride semiconductor, triggers the current collapse, contrary to the description of PTL1. The present inventors considered that the copper (Cu) forms a deep level in the band gap of the nitride semiconductor, causing electrons and holes to be trapped to the level, with the result that the current collapse occurs. The present invention has been created based on such findings and considerations by the present inventors as described above.

A nitride semiconductor growth apparatus of the present invention comprises:

a chamber into which a reactive gas containing nitrogen is to be introduced as a material gas; and

a reaction part which is placed in the chamber and in which the material gas is brought into reaction to grow a nitride semiconductor, wherein

in a region which includes the reaction part and part of an upstream side from the reaction part with respect to a flow of the material gas, a portion to be in contact with the material gas is made from non-copper material.

According to the nitride semiconductor growth apparatus of this invention, in the region which includes the reaction part and the part of the upstream side from the reaction part with respect to the flow of the material gas, the portion to be in contact with the material gas is made from non-copper material (i.e., material containing no copper), so that the material gas can be prevented from being contaminated with copper. As a result, the nitride semiconductor can be prevented from being contaminated with copper, so that formation of a deep level in the band gap of the nitride semiconductor can be prevented. Thus, trapping of electrons and holes to the nitride semiconductor can be avoided, so that occurrence of the current collapse can be suppressed in electron devices including the nitride semiconductor.

In a nitride semiconductor growth apparatus according to one embodiment, the nitride semiconductor growth apparatus comprises

a sealing part for holding a vacuum in the chamber or confining the material gas within the chamber, wherein

the sealing part has a sealing member made from non-copper material.

According to this embodiment, since the sealing member of the sealing part is made from non-copper material, copper contamination of the material gas due to the sealing part can be prevented, so that the nitride semiconductor can be prevented from being contaminated with copper. Thus, the current collapse can be suppressed in power devices including the nitride semiconductor.

In a nitride semiconductor growth apparatus according to one embodiment,

the sealing member (120) is at least one of an O-ring made from fluororubber, a PTFE packing, or a wire made from indium.

According to this embodiment, since the sealing member is at least one of an O-ring made from fluororubber, a PTFE (polytetrafluoroethylene) packing, or a wire made from indium, copper contamination of the nitride semiconductor can be prevented, so that a nitride semiconductor for power devices enabled to suppress the current collapse can be fabricated.

In a nitride semiconductor growth apparatus according to one embodiment,

the reactive gas containing nitrogen is ammonia.

According to this embodiment, since the reactive gas is ammonia, the danger of explosions can be avoided unlike cases in which the reactive gas is hydrazine or dimethylhydrazine.

An epitaxial wafer for nitride semiconductor power devices of the present invention is grown by the nitride semiconductor growth apparatus.

According to the epitaxial wafer for nitride semiconductor power devices of this invention, since the epitaxial wafer is grown with the nitride semiconductor growth apparatus, copper contamination can be avoided so that the current collapse in the power device can be suppressed.

### Advantageous Effects of Invention

According to the nitride semiconductor growth apparatus of this invention, in the region which includes the reaction part and the upstream side from the reaction part with respect to the flow of the material gas, the portion of the nitride semiconductor growth apparatus to be in contact with the material gas are made from non-copper material. Therefore, the material gas can be prevented from being contaminated with copper. As a result, the nitride semiconductor can be prevented from being contaminated with copper, so that formation of a deep level in the band gap of the nitride semiconductor can be prevented. Thus, trapping of electrons and holes to the nitride semiconductor can be avoided, so that occurrence of the current collapse can be suppressed in electron devices including the nitride semiconductor.

Also, according to the epitaxial wafer for nitride semiconductor power devices of this invention, since the epitaxial wafer is grown with the nitride semiconductor growth apparatus, copper contamination can be avoided so that the current collapse in the power device can be suppressed.

### BRIEF DESCRIPTION OF DRAWINGS

FIG. 1 is a schematic view showing a configuration of an MOCVD device which is an embodiment of a nitride semiconductor growth apparatus according to the invention;

FIG. 2A is a sectional view showing an aspect that an O-ring is sandwiched between a flange and a lid member of a gas introducing part of the MOCVD device;

FIG. 2B is a sectional view showing an aspect that a packing made from a Teflon (registered trademark)-related material is sandwiched between a flange and a sealing lid of a current introducing part of the MOCVD device;

FIG. 2C is a sectional view showing an aspect that an indium wire is sandwiched between a flange and a window flame portion of a view port part of the MOCVD device;

FIG. 2D is a sectional view showing an aspect that a copper gasket is sandwiched between flanges of an exhaust part of the MOCVD device;

FIG. 3 is a sectional view of a nitride semiconductor device manufactured with the MOCVD device of the embodiment;

FIG. 4 is a characteristic chart showing a relationship between Cu concentration (atomicity/cm²) in a surface region of an AlGaN barrier layer and collapse value in the nitride semiconductor device;

FIG. 5A is a schematic sectional view showing an aspect that electrons are traveling along an interface between channel GaN layer and AlGaN barrier layer in the nitride semiconductor device;

FIG. 5B is a schematic sectional view showing an aspect that electrons traveling along an interface between channel GaN layer and AlGaN barrier layer are trapped by Cu in a nitride semiconductor device according to a related art; and

FIG. 5C is a schematic sectional view showing an aspect that electrons are traveling along the interface between channel GaN layer and AlGaN barrier layer without being trapped by Cu in the nitride semiconductor device manufactured with the MOCVD device of the embodiment.

### DESCRIPTION OF EMBODIMENTS

Hereinbelow, the present invention will be described in detail by way of embodiments thereof illustrated in the accompanying drawings.

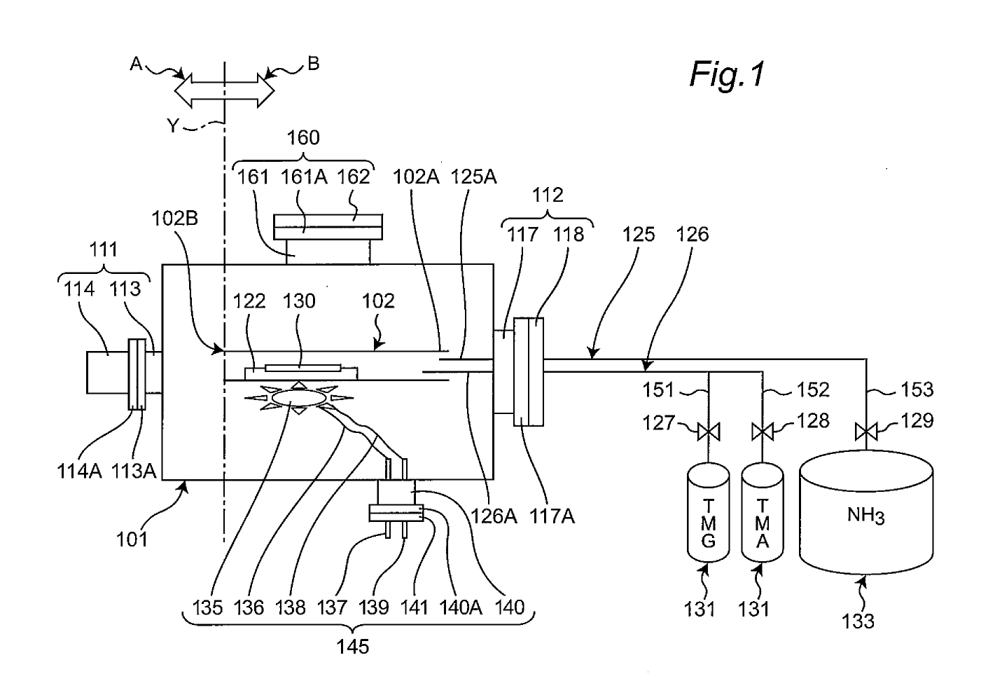

FIG. 1 is a schematic view showing a configuration of an embodiment of a nitride semiconductor growth apparatus according to the invention. The nitride semiconductor growth apparatus of this embodiment is an MOCVD (Metal Organic Chemical Vapor Deposition) device. The MOCVD device includes a chamber 101 and a reaction part 102 provided in the chamber 101. As to the chamber 101 and the reaction part 102, at least their portions to be in contact with material gas are made from a non-copper material containing no copper such as stainless steel. The non-copper material refers to a material containing no copper.

The chamber 101 includes an exhaust part 111 provided downstream of the reaction part 102. Also The chamber 101 includes a gas introducing part 112 provided upstream of the reaction part 102.

The exhaust part 111 includes an exhaust pipe 113 communicating with the chamber 101, and an exhaust duct 114. A flange 113A of the exhaust pipe 113 and a flange 114A of the exhaust duct 114 are tightened with tightening members (not shown) such as bolts.

The gas introducing part 112 has a gas introducing cylinder 117 communicating with the chamber 101, and a lid member 118 tightened to the flange 117A of the gas introducing cylinder 117. The flange 117A of the gas introducing cylinder 117 and the lid member 118 are tightened with tightening members (not shown) such as bolts. As to the gas introducing cylinder 117 and the lid member 118, at least their portions to be in contact with the material gas are made from a non-copper material such as stainless steel.

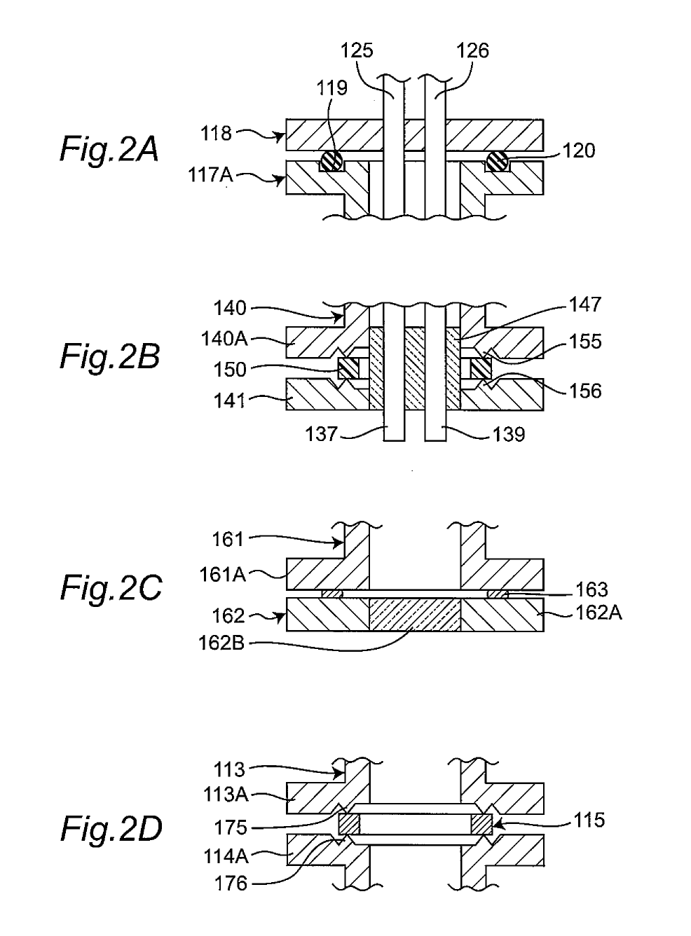

As shown in FIG. 2A, an O-ring 120 as a sealing member is sandwiched between the flange 117A and the lid member 118 of the gas introducing part 112 (shown in FIG. 1). The O-ring 120 is placed at an annular groove 119 formed in an end face of the flange 117A. Also, the O-ring 120 is made from fluororubber such as Viton (registered trademark). In addition, although the tightening member (e.g., bolts) is omitted in FIG. 2A, the tightening member tightens the lid member 118 and the flange 117A at positions radially outer than the O-ring 120.

The flange 117A, the lid member 118, the O-ring 120 and the tightening member (not shown) constitute a sealing part. This sealing part is intended to hold a vacuum in the chamber 101 or confine the material gas to within the chamber 101. In addition, instead of the O-ring 120, a packing made from later-described PTFE (polytetrafluoroethylene) material or an indium wire made from indium may also be used as the sealing member. The indium wire is indeed effective as a sealing member for creating a high vacuum in the chamber 101, but the above-described O-ring or a packing made from a Teflon (registered trademark) material such as PTFE (polytetrafluoroethylene) may also be used when high vacuum is unnecessary.

As shown in FIG. 1, a material gas introducing duct 125 and a material gas introducing duct 126 are provided through the lid member 118. As to the material gas introducing ducts 125, 126, at least their portions to be in contact with the material gas are made from a non-copper material such as stainless steel. Also, the material gas introducing duct 125 and the material gas introducing duct 126 are kept hermetic against the lid member 118 by welding. Fore end portions 125A, 126A of the material gas introducing ducts 125, 126 are positioned at an upstream-side opening 102A of the reaction part 102. Also, the material gas introducing duct 125 is connected to an NH₃ supply source 133 via a pipe joint (not shown), a pipe 153 and a flow regulating valve 129. Further, the material gas introducing duct 126 is connected to a TMG (trimethylgallium) supply source 131 via a pipe joint (not shown), a pipe 151 and a flow regulating valve 127. The material gas introducing duct 126 is also connected to a TMA (trimethylaluminum) supply source 132 via a pipe joint (not shown), a pipe 152 and a flow regulating valve 128. In addition, as to the individual pipe joints, the pipes 151, 152, 153 and the flow regulating valves 127, 128, 129, at least their portions to be in contact with the material gas are made from a non-copper material such as stainless steel.

Meanwhile, as shown in FIG. 2D, a copper gasket 115 as a sealing member is sandwiched between the flange 113A of the exhaust pipe 113 and the flange 114A of the exhaust duct 114 in the exhaust part 111 (shown in FIG. 1). The copper gasket 115 is a copper ring satisfying a specification such as ICF or CF as an example. The copper gasket 115 is sandwiched between an annular protrusion 175 formed in an end face of the flange 113A and an annular protrusion 176 formed in a rear face of the flange 114A. The copper gasket 115 is effective as a sealing member for creating a high-vacuum in the chamber 101. Also, the flange 113A and the flange 114A are tightened by tightening members (not shown) such as bolts. The flanges 113A, 114A, the copper gasket 115 and the tightening members (not shown) constitute a sealing part. An exhaust pump (not shown) is connected to the exhaust duct 114 of the exhaust part 111, and gas in the chamber 101 is exhausted to reduce a pressure in the chamber by this exhaust pump. The exhaust pipe 113 and the exhaust duct 114 of the exhaust part 111 shown in FIG. 1, although made from a non-copper material containing no copper such as stainless steel in this embodiment, yet may also be made from a copper material containing copper.

In the reaction part 102, as shown in FIG. 1, a mounting plate 122 is provided, and a substrate 130 is mounted on this mounting plate 122. The fore end portions 125A, 126A of the material gas introducing ducts 125, 126 are placed at the upstream-side opening 102A of the reaction part 102. The material gas introducing ducts 125, 126 extend through the gas introducing cylinder 117. As to the reaction part 102 and the mounting plate 122, at least their portions to be in contact with the material gas are made from a non-copper material such as stainless steel.

Also, the reaction part 102 includes a heater 135 for heating the mounting plate 122. The heater 135 is connected to current leading terminals 137, 139 with current supply lines 136, 138. The current supply lines 136, 138 and the current leading terminals 137, 139 were made from nickel as a non-copper material.

The current leading terminals 137, 139 are inserted into a terminal insertion tube 140 communicating with the chamber 101. The terminal insertion tube 140 has a flange 140A, and the flange 140A is tightened to a sealing lid 141 with a tightening member (not shown) such as bolts. As to the terminal insertion tube 140 and the sealing lid 141, at least their portions to be in contact with the material gas are made from a non-copper material such as stainless steel. The current supply lines 136, 138, the current leading terminals 137, 139, the terminal insertion tube 140 and the sealing lid 141 constitute a current introducing part 145.

As shown in FIG. 2B, an annular packing 150 as a sealing member is sandwiched between the flange 140A of the terminal insertion tube 140 and the sealing lid 141. This packing 150 is made from a Teflon (registered trademark)-related material such as PTFE (polytetrafluoroethylene). The packing 150 is sandwiched between an annular protrusion 155 formed in an end face of the flange 140A and an annular protrusion 156 formed in a rear face of the sealing lid 141. Also, the flange 140A and the sealing lid 141 are tightened with tightening members (not shown) such as bolts at positions radially outer than the packing 150. Also, the current leading terminals 137, 139 are inserted into a dielectric ceramic 147 and fixed to the sealing lid 141 by silver soldering or the like so as to be hermetically fitted. The dielectric ceramic 147 has high hermetic sealing property and high dielectric property. The flange 140A, the sealing lid 141, the packing 150 and the tightening members (not shown) constitute a sealing part. This sealing part is intended to hold a vacuum in the chamber 101 or confine the material gas to within the chamber 101. In addition, instead of the sealing part using the packing 150 shown in FIG. 2B, a sealing part using the O-ring shown in FIG. 2A or a sealing part using the indium ring shown in FIG. 2C may also be adopted.

Also as shown in FIG. 1, the chamber 101 includes a view port part 160 provided so as to be positioned above the reaction part 102. The view port part 160 has a cylinder portion 161 communicating with the chamber 101, and a window portion 162 tightened to a flange 161A of the cylinder portion 161. As to the cylinder portion 161, at least its portion to be in contact with the material gas is made from a non-copper material such as stainless steel.

As shown in FIG. 2C, an indium wire 163 made from indium as a sealing member is sandwiched between the flange 161A of the cylinder portion 161 and a window frame portion 162A of the window portion 162. A heat-resistant glass 162B such as quartz glass is fitted into the window frame portion 162A. The heat-resistant glass 162B is fixed to the window portion 162 with an adhesive made from a non-copper material. As to the window frame portion 162A, at least its portion to be in contact with the material gas is made from a non-copper material such as stainless steel. The non-copper material refers to a material containing no copper.

The flange 161A and the window portion 162 are tightened by a tightening member (not shown) such as bolts. The flange 161A, the window portion 162, the indium wire 163 and the tightening member (not shown) constitute a sealing part. This sealing part is intended to hold a vacuum in the chamber 101 or confine the material gas to within the chamber 101. In addition, instead of the sealing part using the indium wire 163 shown in FIG. 2C, a sealing part using the O-ring shown in FIG. 2A or a sealing part using the packing made from a Teflon (registered trademark) material shown in FIG. 2B may also be adopted.

As described above, in an upstream-side region indicated by arrow B ranging from a downstream end 102B of the reaction part 102 indicated by one-dot chain line Y with respect to a flow of the material gas as shown in FIG. 1, the portion of the MOCVD device to be in contact with the material gas is made from non-copper materials containing no copper.

In this MOCVD device, the copper gasket 115 (shown in FIG. 2D) is used as the sealing member of the exhaust part 111 in the downstream-side region indicated by arrow A ranging from the downstream end 102B of the reaction part 102 indicated by the one-dot chain line Y. Alternatively, as the sealing member, an O-ring made from fluororubber, a PTFE packing or an indium ring may also be adopted as in the cases of the gas introducing part 112, the current introducing part 145 and the view port part 160. Even if the copper gasket 115 is used in the downstream side of the reaction part 102 so that copper reacts with the material gas, copper is not taken into the wafer but discharged out so that the use of the copper gasket 115 does not matter. Further, since the sealing member by use of the O-ring made from fluororubber, the PTFE packing or the indium ring is lower in heat resistance than the copper gasket, it is desirable that an unshown cooling jacket or the like be attached to those sealing parts (flange, lid member, etc.) with the O-ring, the packing or the indium ring mounted so that a cooling medium (cooling water etc.) is circulated through the cooling jacket to cool the sealing parts.

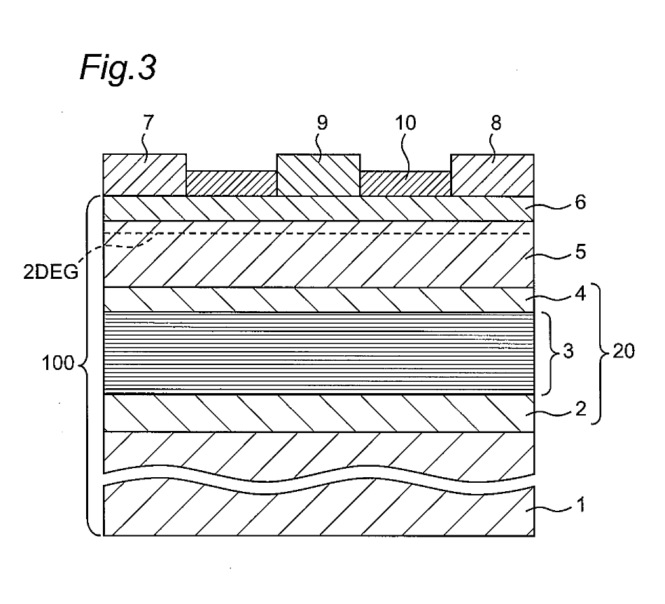

Next, process for manufacturing the nitride semiconductor device shown in FIG. 3 with the MOCVD device in this embodiment will be explained below.

First, a Si substrate 1 is cleaned with a 10% HF (Hydrofluoric acid) solution and thereafter introduced into the MOCVD (Metal Organic Chemical Vapor Deposition) device.

The Si substrate 1 is heated to a substrate temperature of 1100° C. in a hydrogen atmosphere with a flow rate of 10 slm (Standard Liter per Minute: L/min.), thus subjected to surface cleaning. More strictly, hydrogen is introduced into the chamber 101 (shown in FIG. 1) via a gas line, which is not shown in FIG. 1, other than gas lines for organic metal and ammonia.

Then, a buffer layer 20, a channel GaN layer 5, and an AlGaN barrier layer 6 are stacked sequentially on the Si substrate 1.

In this case, the AlN seed layer 2 is grown with a growth pressure of 13.3 kPa and a substrate temperature of 1100° C. As materials of AlN to form the AlN seed layer 2, TMA (trimethylaluminum) with a flow rate of 100 μmol/min. and NH₃ (ammonia) with a flow rate of 12.5 slm are supplied. The TMA is introduced from the TMA supply source 132 (shown in FIG. 1) via the gas introducing part 112 (shown in FIG. 1) into the chamber 101, while the NH₃ is introduced from the NH₃ supply source 133 via the gas introducing part 112 into the chamber 101. The substrate temperature is controlled by controlling the power of the heater 135.

The superlattice layer 3 is grown with a growth pressure of 13.3 kPa and a substrate temperature of 1100° C. as in the case of the AlN seed layer 2. For formation of the superlattice layer 3, materials to be supplied are alternately switched over so that AlN and Al_{0.1}Ga_{0.9}N are stacked in layers. As an example, a superlattice layer composed of a 3 nm thick layer of AlN and a 20 nm thick layer of Al_{0.1}Ga_{0.9}N is stacked in repetitions of 120 times to form the superlattice layer 3. As materials of Al_{0.1}Ga_{0.9}N, TMA with a flow rate of 80 μmol/min., TMG (trimethylgallium) with a flow rate of 720 μmol/min., and NH₃ with a flow rate of 12.5 slm are supplied. In addition, materials for AlN of the superlattice layer 3 are supplied as in the case of the AlN seed layer 2.

The carbon-doped GaN layer 4 is grown with a growth pressure of 13.3 kPa and a substrate temperature of 1100° C. as in the case of the AlN seed layer 2. As materials of GaN to form the carbon-doped GaN layer 4 as the carbon-doped GaN layer 4, TMG with a flow rate of 720 μmol/min. and NH₃ with a flow rate of 12.5 slm are supplied.

The channel GaN layer 5 is grown with a growth pressure of 100 kPa and a substrate temperature of 1100° C. As materials of GaN to form the channel GaN layer 5 as the channel GaN layer 5, TMG with a flow rate of 100 μmol/min. and NH₃ with a flow rate of 12.5 slm are supplied. The layer thickness of the channel GaN layer 5 is set to 1 μm as an example. The TMG is introduced from the TMG supply source 131 via the gas introducing part 112 into the chamber 101.

The AlGaN barrier layer 6 is grown with a growth pressure of 13.3 kPa and a substrate temperature of 1100° C. as in the case of the AlN seed layer 2. As materials of Al_{0.17}Ga_{0.83}N to form the AlGaN barrier layer 6 as the AlGaN barrier layer 6, TMA with a flow rate of 8 μmol/min., TMG with a flow rate of 50 μmol/min., and NH₃ with a flow rate of 12.5 slm are supplied.

Next, with use of epitaxial wafers fabricated as described above, a source electrode 7, a drain electrode 8 and a gate electrode 9 are formed on the AlGaN barrier layer 6. The manufacturing method for the source electrode 7, the drain electrode 8 and the gate electrode 9 is not particularly limited, but a known method such as vapor deposition may be used. The epitaxial wafers described above become epitaxial wafers for nitride semiconductor power devices.

For example, the source/drain region is patterned and an ohmic electrode is deposited thereon. After lift-off, heat treatment for ohmic process is applied so that the source electrode 7 and the drain electrode 8 are formed. Conditions for this heat treatment, although varying depending on the film thickness of metal, are set to 800° C. for 1 min. in a nitrogen atmosphere in this embodiment. By this heat treatment, ohmic contact between the AlGaN barrier layer 6 and the source electrode 7 as well as ohmic contact between the AlGaN barrier layer 6 and the drain electrode 8 are obtained. Also, a distance between the source electrode 7 and the drain electrode 8 is adjusted depending on desired performance of the field effect transistor.

Next, a region where the gate electrode 9 is to be deposited is patterned, so that the gate electrode 9 is formed. Pt, Ni, Pd, WN and the like are usable as the gate electrode 9. WN is used in this embodiment. Thereafter, an insulating film 10 made from SiN is formed on the AlGaN barrier layer 6 by a known method such as plasma CVD.

The order for formation of the source electrode 7, the drain electrode 8, the gate electrode 9 and the insulating film 10 is not particularly limited. The insulating film 10 may be formed first. Also, the ohmic electrode metal may be Hf/Al/Hf/Au or Ti/Al/Mo/Au.

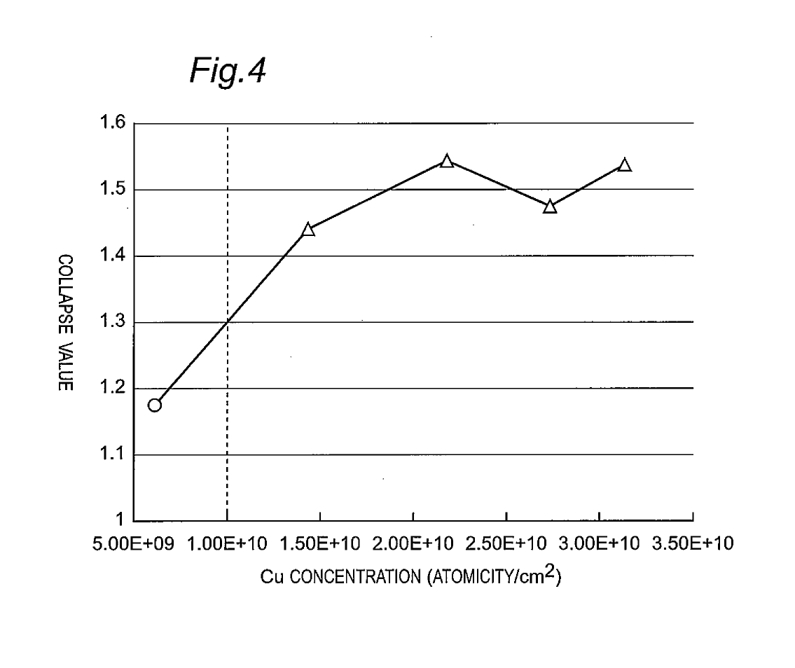

FIG. 4 shows a relationship between collapse value and Cu concentration (atomicity/cm²) in a surface region of 10 nm or less depths from the surface of the AlGaN barrier layer 6 in the nitride semiconductor device. In FIG. 4, E+09, E+10 in the horizontal axis represent 10⁹, 10¹⁰, respectively.

The collapse value is a value expressed by a ratio of on-resistance R1 to on-resistance R2 (R2/R1). The on-resistance R1 is a value resulting when a voltage of 1 V is applied to between the source electrode 7 and the drain electrode 8. The on-resistance R2 is a value resulting at a time point when 5 microseconds have elapsed after a switchover from an off state to an on state in a state that applying a voltage of 500 V to between the source electrode 7 and the drain electrode 8 in the off state and thereafter applying a voltage of 1 V to between the source electrode 7 and the drain electrode 8 in the on state, where a negative voltage is applied to the gate electrode 9 in the Off state and the voltage of the gate electrode 9 is set to zero volts in the on state. It is noted that the on-resistance is defined by device size (e.g., the distance between the source electrode 7 and the drain electrode 8, the area of electrodes).

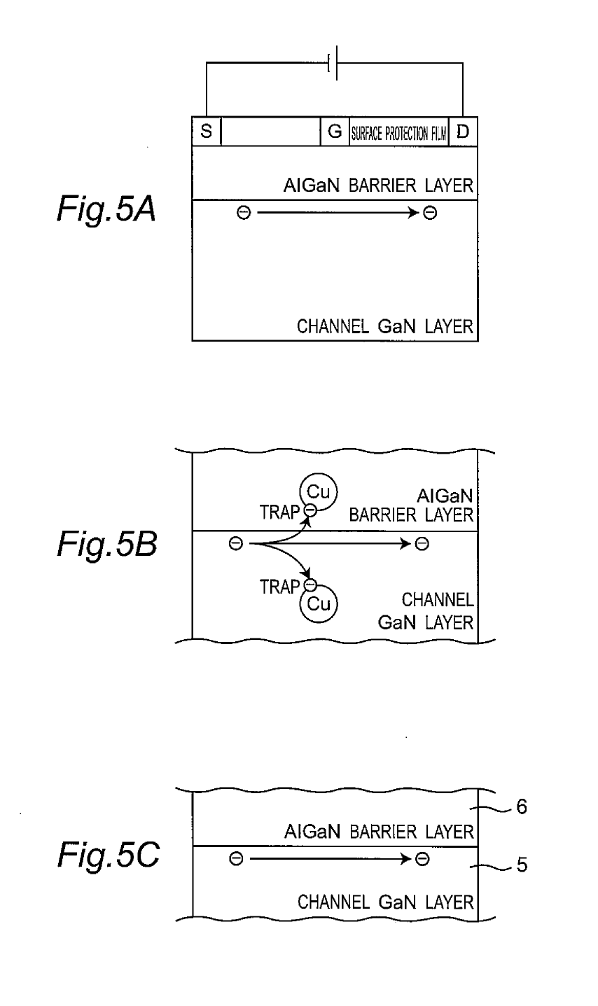

In one example of the group III nitride semiconductor multilayer substrate 100 (shown in FIG. 5) fabricated with the MOCVD device described above with reference to FIG. 1, the Cu concentration (atomicity/cm²) in the surface region of the AlGaN barrier layer 6, as shown by the plot of ◯ mark, was 6.1×10⁹ (atomicity/cm²), which is lower than 1.0×10¹⁰ (atomicity/cm²). Also, in another example of the group III nitride semiconductor multilayer substrate fabricated by the same process as described above with the MOCVD device, the Cu concentration (atomicity/cm²) in the surface region of the AlGaN barrier layer 6 was under 3×10 (atomicity/cm²), which is a detection limit by the TXRF method (Total reflection X-Ray Fluorescence Method).

The TXRF method is capable of efficiently detecting fluorescent X-rays from metal pollutants present on the substrate surface because fluorescent X-rays generated on the substrate side as well as scattered rays incident on the detector are reduced by applying an excited X-ray to the surface of the AlGaN barrier layer 6 at a lower angle (e.g., 0.1°) as compared with the XRF method (X-ray Fluorescence Method).

Meanwhile, in a nitride semiconductor multilayer substrate of the comparative example fabricated with a conventionally available MOCVD device, in which copper (e.g., a copper gasket of ICF specification) was used at such portions as the sealing members of the gas introducing part, the current introducing part and the view port part as well as the portion of the current leading terminals and the like unlike the MOCVD device described above with reference to FIG. 1, the Cu concentration (atomicity/cm²) in the surface region of the AlGaN barrier layer, as indicated by plots of Δ mark in FIG. 4, was 1.44×10¹⁰ (atomicity/cm²), 2.18×10¹⁰ (atomicity/cm²), 2.74×10¹⁰ (atomicity/cm²), or 3.13×10¹⁰ (atomicity/cm²), where all of the values were over 1.0×10″ (atomicity/cm²).

As can be understood from FIG. 4, in the GaN HFET of the comparative example having the AlGaN barrier layer in which those Cu concentrations (atomicity/cm²) in the surface region were over 1.0×10¹⁰ (atomicity/cm²), the collapse value resulted in 1.44 to 1.54, that is, all of the collapse values were beyond 1.3.

In contrast to this, according to one example of the nitride semiconductor device (GaN HFET) including the group III nitride semiconductor multilayer substrate 100 of this embodiment, a collapse value of 1.18 was able to be achieved. Also, in another example in which the Cu concentration (atomicity/cm²) was lower than the detection limit by the TXRF method, a collapse value of 1.10 was able to be achieved.

For nitride semiconductor devices (GaN HFETs), attaining a collapse value of 1.3 or lower is of importance in order that the devices are established as commercial products. That is, GaN HFETs having a collapse value of 1.3 or lower have commercial values in terms of performance and cost as a product capable of larger current driving than silicon devices and suitable for high-temperature operations.

As schematically shown in FIG. 5A, such a voltage is applied to between drain electrode D and source electrode S that the drain D goes a high potential, and the voltage of the gate electrode G is set to zero. Then, electrons run in a direction from the source toward the drain through the 2DEG (2-Dimensional Electron Gas) layer formed between the AlGaN barrier layer and the channel GaN layer. In this case, as schematically shown in FIG. 5B, it can be considered that with Cu (copper) contained in the AlGaN barrier layer, electrons are trapped at deeper levels of Cu so that the drain current decreases, causing the on-resistance to increase with the result that the collapse value is increased. In contrast to this, according to the group III nitride semiconductor multilayer substrate 100 fabricated with the MOCVD device of this embodiment, it can be considered that since the Cu concentration (atomicity/cm²) in the surface region of the AlGaN barrier layer 6 is reduced to 1.0×10¹⁰ (atomicity/cm²) or lower, electrons trapped to Cu are reduced so that the drain current can be increased, causing the on-resistance to decrease with the result that the collapse value can be suppressed as schematically shown in FIG. 5C.

The MOCVD device of this embodiment has been described on a case where a group III nitride semiconductor multilayer substrates using a Si substrate is fabricated. However, without being limited to the Si substrate, it is also allowable to use a sapphire substrate or SiC substrate, where a nitride semiconductor layer may be grown on the sapphire substrate or SiC substrate. A nitride semiconductor layer may be grown on a substrate formed from a nitride semiconductor such as growing an AlGaN layer on a GaN substrate. Furthermore, the buffer layer may not be formed between the substrate and the nitride semiconductor layer.

Although the nitride semiconductor growth apparatus of this invention may be applied not only to MOCVD devices but also other thermal CVD devices, yet the invention is applied to non-plasma type thermal reaction devices using not plasma but thermal reaction. Using plasma in combination with a material gas of ammonia (NH₃) would involve generation of hydrazine. Since the resulting hydrazine has explosiveness involving danger, plasma is not used in this invention.

The MOCVD device of this embodiment also has been described on a case where an HFET of the normally-ON type is fabricated. Instead, the invention may also be applied to nitride semiconductor growth apparatuses for fabricating nitride semiconductor devices of the normally-OFF type. Further, without being limited to cases where a nitride semiconductor device in which the gate electrode is a Schottky electrode is fabricated, the nitride semiconductor growth apparatus of this invention may also be used in cases where field effect transistors of the insulated-gate structure are fabricated.

The nitride semiconductor for the group III nitride semiconductor multilayer substrate fabricated with use of the nitride semiconductor growth apparatus of this invention needs to be those expressed by AlₓIn_{y}Ga_{1-x-y}N (x≧0, y≧0, 0≦x+y≦1).

Further, the nitride semiconductor device fabricated by using the nitride semiconductor growth apparatus of this invention is not limited to HFETs using 2DEG and may be applied also to field effect transistors of other structures, in which case also similar effects can be obtained.

Although a specific embodiment of the present invention has been described hereinabove, yet the invention is not limited to the above embodiment and may be carried out as it is changed and modified in various ways within the scope of the invention.

### REFERENCE SIGNS LIST

1 Si substrate
2 AlN seed layer
3 superlattice layer
4 carbon-doped GaN layer
5 channel GaN layer
6 AlGaN barrier layer
7 source electrode
8 drain electrode
9 gate electrode
10 insulating film
20 buffer layer
100 group III nitride semiconductor multilayer substrate
101 chamber
102 reaction part
102A upstream-side opening
111 exhaust part
112 gas introducing part
113 exhaust pipe
113A, 114A, 117A, 140A, 161A flange
114 exhaust duct
115 copper gasket
117 gas introducing cylinder
118 lid member
120 O-ring
122 mounting plate
125, 126 material gas introducing duct
127, 128, 129 flow regulating valve
130 substrate
131 TMG supply source
132 TMA supply source
133 NH₃ supply source
135 heater
136, 138 current supply line
137, 139 current leading terminal
140 terminal insertion tube
141 sealing lid
150 packing
151, 152, 153 pipe
160 view port part
161 cylinder portion
162 window portion
163 indium wire

1-5. (canceled)

6. A nitride semiconductor growth apparatus comprising:
a chamber into which a reactive gas containing nitrogen is to be introduced as a material gas; and
a reaction part which is placed in the chamber and in which the material gas is brought into reaction to grow a nitride semiconductor, wherein
in a region which includes the reaction part and part of an upstream side from the reaction part with respect to a flow of the material gas, a portion to be in contact with the material gas is made from non-copper material.

7. The nitride semiconductor growth apparatus as claimed in claim 6, further comprising
a sealing part for holding a vacuum in the chamber or confining the material gas within the chamber, wherein
the sealing part has a sealing member made from non-copper material.

8. The nitride semiconductor growth apparatus as claimed in claim 7, wherein
the sealing member is
at least one of an O-ring made from fluororubber, a PTFE packing, or a wire made from indium.

9. The nitride semiconductor growth apparatus as claimed in claim 6, wherein
the reactive gas containing nitrogen is ammonia.

10. An epitaxial wafer for nitride semiconductor power devices which is grown by the nitride semiconductor growth apparatus as defined in claim 6.
